(19) United States
(12) Patent Application Publication
(10) Pub. No.: US 2025/0341603 A1
(43) Pub. Date: Nov. 6, 2025

(54) ABNORMALITY DETECTION DEVICE

(71) Applicants: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(72) Inventors: Muneyoshi YABUTA, Yokkaichi-Shi, Mie (JP); Takahiro KURATOMI, Yokkaichi-Shi, Mie (JP); Seiji TAKAHASHI, Yokkaichi-Shi, Mie (JP)

(73) Assignees: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(21) Appl. No.: 18/855,408

(22) PCT Filed: Apr. 13, 2022
(86) PCT No.: PCT/JP2022/017716

§ 371 Date: Oct. 9, 2024

(51) Int. Cl. G01R 35/00; G01R 15/14; G01R 15/20; G01R 19/10

(52) U.S. Cl. CPC G01R 35/00; G01R 15/146; G01R 15/20; G01R 19/10

(57) ABSTRACT

An abnormality detection device includes a parallel circuit unit in which a plurality of conductive paths are connected in parallel, a plurality of current sensors, and an abnormality determination unit. The current sensors respectively detect currents flowing through the plurality of conductive paths. The abnormality determination unit performs abnormality determination of the current sensors based on the respective detection values of the plurality of current sensors. In the abnormality detection device, currents distributed between the plurality of conductive paths are detected by the respective current sensor, and abnormality determination of the current sensors is performed based on the detection values. Accordingly, with this configuration, the current tolerance of the individual current sensors can be reduced, and thus the current sensors can be easily downsized.

### CROSS-REFERENCE TO RELATED APPLICATIONS

This application is the U.S. national stage of PCT/JP2022/017716 filed on Apr. 13, 2022 the contents of which is incorporated herein.

### TECHNICAL FIELD

The present disclosure relates to an abnormality detection device.

### BACKGROUND

JP 2021-515194T discloses a device for diagnosing an error in current sensors. This device includes two current sensors for measuring a current value of a current flowing through the same path. The device diagnoses an error in the current sensors based on the comparison result of the measurement values of the two current sensors. Note that JP 2013-90474A also discloses a device for detecting an abnormality in current sensors.

In the technique for detecting an abnormality in the current sensors as described above, it is desired to downsize the current sensors.

The present disclosure provides a technique according to which current sensors are easily downsized in a configuration in which an abnormality in the current sensors is detected.

### SUMMARY

An abnormality detection device according to the present disclosure is an abnormality detection device including: a parallel circuit unit in which a plurality of conductive paths are connected in parallel; a plurality of current sensors; and an abnormality determination unit, wherein the current sensors detect currents respectively flowing through the plurality of conductive paths, and the abnormality determination unit performs abnormality determination of the current sensors based on the detection values of the plurality of current sensors.

### Advantageous Effects

According to the technique of the present disclosure, current sensors can be easily downsized in a configuration in which an abnormality in the current sensors is detected.

### BRIEF DESCRIPTION OF DRAWINGS

FIG. 1 is a configuration diagram schematically illustrating a power supply system including an abnormality detection device according to a first embodiment.

FIG. 2 is a configuration diagram schematically illustrating a power supply system including an abnormality detection device according to a second embodiment.

### DETAILED DESCRIPTION OF PREFERRED EMBODIMENTS

Hereinafter, embodiments of the present disclosure will be listed and described.

In a first aspect, an abnormality detection device includes a parallel circuit unit in which a plurality of conductive paths are connected in parallel; a plurality of current sensors; and an abnormality determination unit, wherein the current sensors detect currents respectively flowing through the plurality of conductive paths, and the abnormality determination unit performs abnormality determination of the current sensors based on the detection values of the plurality of current sensors.

In the above abnormality detection device, currents distributed between the plurality of conductive paths are detected by the respective current sensors, and abnormality determination of the current sensors is performed based on the detection values. Accordingly, with this configuration, since the current capacity of individual current sensors can be reduced, the current sensors can be easily downsized.

In a second aspect, the abnormality detection device according to the first aspect, in which the plurality of conductive paths include a first conductive path and a second conductive path connected in parallel to each other, the plurality of current sensors include a first current sensor that detects a current flowing through the first conductive path, and a second current sensor that detects a current flowing through the second conductive path, and the abnormality determination unit determines that there is an abnormality at least when a difference between a detection value of the first current sensor and a detection value of the second current sensor is outside a predetermined numerical range.

With this configuration, the configuration for performing abnormality determination of the current sensors can be more easily simplified.

In a third aspect, the abnormality detection device according to the first or the second aspects, in which the parallel circuit unit is provided between a power supply unit and a power supply target to which power based on the power supply unit is to be supplied, and the abnormality detection device further includes an interruption unit configured to switch from a permission state in which power supply from the power supply unit side to the power supply target side via the parallel circuit unit is permitted to an interruption state in which the power supply is interrupted.

With this configuration, by the interruption unit switching from the permission state to the interruption state, the power supply from the power supply unit side to the power supply target side via the parallel circuit unit can be interrupted.

In a fourth aspect, the abnormality detection device according to the third aspect, further comprising a control unit configured to switch the interruption unit from the permission state to the interruption state based on a detection value of at least one of the plurality of current sensors.

According to this configuration, the power supply from the power supply unit side to the power supply target side via the parallel circuit unit can be interrupted based on the detection values of the current sensors. Further, an abnormality of the current sensors used for determination regarding switching of the interruption unit can be determined by the abnormality determination unit.

In a fifth aspect, the abnormality detection device according to the fourth aspect, in which the control unit determines whether or not each of the conductive paths is in an overcurrent state, based on a detection value of the corresponding current sensor, and when it is determined that at least one of the conductive paths is in the overcurrent state, switches the interruption unit from the permission state to the interruption state.

With this configuration, the plurality of current sensors used for determination of an abnormality can be effectively used for quick switching of the interruption unit.

In a sixth aspect, the abnormality detection device according to the fourth aspect, in which the control unit determines whether or not each of the conductive paths is in an overcurrent state based on a detection value of the corresponding current sensor, and when it is determined that two or more of the conductive paths are in the overcurrent state, switches the interruption unit from the permission state to the interruption state.

With this configuration, the plurality of current sensors used for determination of an abnormality can be effectively used for prevention of erroneous determination of the overcurrent state.

In a seventh aspect, the abnormality detection device according to any one of the first through the sixth aspects, in which the parallel circuit unit is provided between the power supply unit and the power supply target to which power based on the power supply unit is to be supplied, and one end of the parallel circuit unit is electrically connected to a power supply unit side conductive path provided on the power supply unit side with respect to the parallel circuit unit, and the other end of the parallel circuit unit is electrically connected to a target side conductive path provided on the power supply target side with respect to the parallel circuit unit.

With this configuration, it is possible to detect an abnormality in the current sensor for detecting a current supplied from the power supply unit to the power supply target.

In an eighth aspect, the abnormality detection device according to any one of the first through the seventh aspects, in which each of the current sensors has a shunt resistor provided in the corresponding conductive path.

With this configuration, the configuration of the current sensors can be easily simplified.

In a ninth aspect, the abnormality detection device according to the first through the seventh aspects, in which each of the current sensors includes a magnetism detection unit configured to detect magnetism generated by a current flowing through each of the conductive paths and convert the magnetism into an electric signal.

With this configuration, currents flowing through the conductive paths can be detected without providing a resistor in the conductive paths.

### First Embodiment

### Configuration of Power Supply System 1

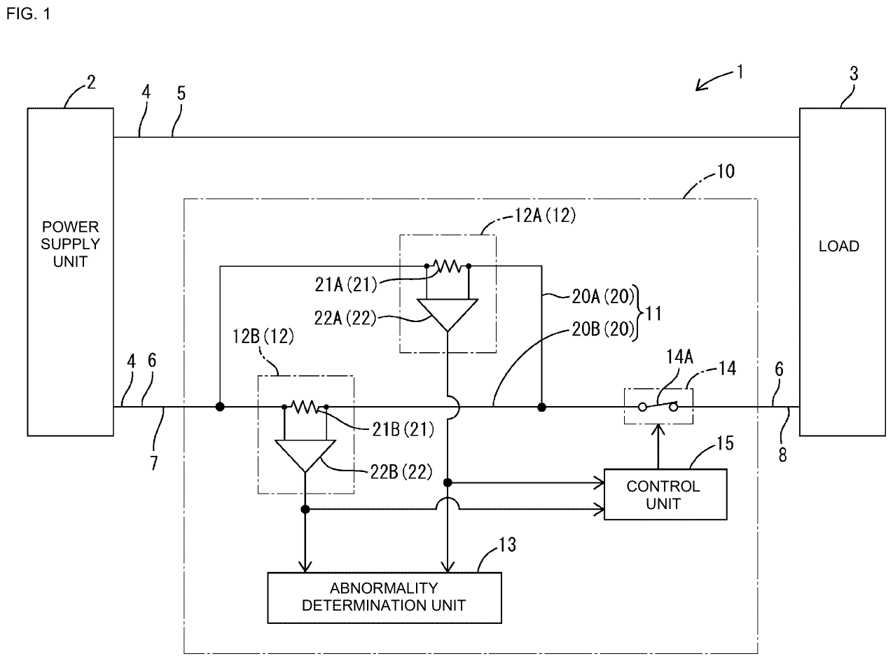

FIG. 1 shows a power supply system 1 including an abnormality detection device 10 of a first embodiment. The power supply system 1 is a system mounted in a vehicle, and capable of supplying power to various power supply targets. The power supply system 1 includes a power supply unit 2, a load 3, a power path 4, and the abnormality detection device 10.

The power path 4 is provided between the power supply unit 2 and the load 3, and functions as a path for supplying power from the power supply unit 2 to the load 3. The power path 4 includes a positive electrode side conductive path 5 and a negative electrode side conductive path 6.

The power supply unit 2 is a vehicle-mounted power supply capable of supplying power to the load 3. The power supply unit 2 is constituted as a known vehicle-mounted battery such as a lead battery. The power supply unit 2 may be constituted by a battery other than a lead battery, and may include a power supply means other than a battery instead of or in addition to a battery. The positive electrode of the power supply unit 2 is short-circuited to one end of the positive electrode side conductive path 5 and electrically connected to the one end of the positive electrode side conductive path 5. The negative electrode of the power supply unit 2 is short-circuited to one end of the negative electrode side conductive path 6 and electrically connected to the one end of the negative electrode side conductive path 6. The power supply unit 2 applies a predetermined DC voltage (e.g., 12 V) to the power path 4 when fully charged. The power supply unit 2 supplies power to the power path 4 and also supplies power to the load 3 via the power path 4.

The load 3, which corresponds to an example of the power supply target, is an electric component that is mounted in a vehicle. The load 3 operates using power supplied via the power path 4. One end of the load 3 is short-circuited to the other end of the positive electrode side conductive path 5 and electrically connected to the other end of the positive electrode side conductive path 5. The other end of the load 3 is short-circuited to the other end of the negative electrode side conductive path 6 and electrically connected to the other end of the negative electrode side conductive path 6.

The abnormality detection device 10 is mounted in a vehicle and used in the power supply system 1. The abnormality detection device 10 includes a parallel circuit unit 11, a plurality of current sensors 12, an abnormality determination unit 13, an interruption unit 14, and a control unit 15.

The parallel circuit unit 11 has a configuration in which a plurality of conductive paths 20 are connected in parallel to each other. The parallel circuit unit 11 is provided between the power supply unit 2 and the load 3. The parallel circuit unit 11 is provided in the power path 4 (more specifically, the negative electrode side conductive path 6) and forms part of the power path 4 (more specifically, the negative electrode side conductive path 6). In other words, the parallel circuit unit 11 forms part of a path for supplying power from the power supply unit 2 to the load 3. One end of the parallel circuit unit 11 is short-circuited to a power supply unit side conductive path 7 that is provided on the power supply unit 2 side relative to the parallel circuit unit 11, and electrically connected to the power supply unit side conductive path 7. The other end of the parallel circuit unit 11 is electrically connected to a target side conductive path 8 that is provided on the load 3 side relative to the parallel circuit unit 11. The plurality of conductive paths 20 are connected in parallel between the power supply unit side conductive path 7 and the target side conductive path 8.

The power supply unit side conductive path 7 and the target side conductive path 8 form part of the negative electrode side conductive path 6. One end of the power supply unit side conductive path 7 is short-circuited to a negative electrode of the power supply unit 2 and electrically connected to the negative electrode of the power supply unit 2. The other end of the power supply unit side conductive path 7 is short-circuited to the one end of the parallel circuit unit 11 and is electrically connected to the one end of the parallel circuit unit 11. One end of the target side conductive path 8 is short-circuited to the other end of the load 3 and is electrically connected to the other end of the load 3. The other end of the target side conductive path 8 is short-circuited to the other end of the parallel circuit unit 11 and is electrically connected to the other end of the parallel circuit unit 11.

The plurality of conductive paths 20 include a first conductive path 20A and a second conductive path 20B. The first conductive path 20A and the second conductive path 20B are connected in parallel between the power supply unit side conductive path 7 and the target side conductive path 8. One end of each conductive path 20 is short-circuited to the power supply unit side conductive path 7 (more specifically, the other end of the power supply unit side conductive path 7) and electrically connected to the power supply unit side conductive path 7 (more specifically, the other end of the power supply unit side conductive path 7). The other end of each conductive path 20 is short-circuited to the target side conductive path 8 (more specifically, the other end of the target side conductive path 8) and electrically connected to the target side conductive path 8 (more specifically, the other end of the target side conductive path 8).

Each current sensor 12 detects a current flowing through the corresponding conductive path 20. The plurality of current sensors 12 include a first current sensor 12A and a second current sensor 12B. The first current sensor 12A detects a current flowing through the first conductive path 20A. The second current sensor 12B detects a current flowing through the second conductive path 20B. Information with which the detection values of the current sensors 12 can be specified is input to the abnormality determination unit 13 and the control unit 15.

The current sensors 12 each include a shunt resistor 21 provided in the corresponding conductive path 20, and a differential amplification circuit 22 for amplifying and outputting the potential difference between the two ends of the shunt resistor 21. One end of each shunt resistor 21 is short-circuited to the power supply unit side conductive path 7 (more specifically, the other end of the power supply unit side conductive path 7) and electrically connected to the power supply unit side conductive path 7 (more specifically, the other end of the power supply unit side conductive path 7). The other end of each of the shunt resistor 21 is short-circuited to the target side conductive path 8 (more specifically, the other end of the target side conductive path 8) and electrically connected to the target side conductive path 8 (more specifically, the other end of the target side conductive path 8).

The first current sensor 12A includes a first shunt resistor 21A provided in the first conductive path 20A and a first differential amplification circuit 22A for amplifying and outputting the potential difference between the two ends of the first shunt resistor 21A. The second current sensor 12B includes a second shunt resistor 21B provided in the second conductive path 20B and a second differential amplification circuit 22B for amplifying and outputting the potential difference between the two ends of the second shunt resistor 21B. The resistance value of the first shunt resistor 21A is the same as the resistance value of the second shunt resistor 21B.

The abnormality determination unit 13 includes an information processing device such as a Micro Controller Unit (MCU). The detection value of each of the current sensors 12 is input to the abnormality determination unit 13. The abnormality determination unit 13 performs abnormality determination of the current sensors 12 based on the detection value of each of the current sensors 12. In the present embodiment, the abnormality determination unit 13 determines that there is an abnormality in at least one of the first current sensor 12A and the second current sensor 12B, based on the detection value of the first current sensor 12A and the detection value of the second current sensor 12B. The abnormality determination unit 13 determines that there is an abnormality when the difference between the detection value of the first current sensor 12A and the detection value of the second current sensor 12B is outside a predetermined numerical range.

The interruption unit 14 has a function of switching from a permission state in which power supply from the power supply unit 2 side to the load 3 side via the parallel circuit unit 11 is permitted to an interruption state in which the power supply is interrupted. The interruption unit 14 includes a switch 14A in the present embodiment. The switch 14A may be a semiconductor switch such as a Field Effect Transistor (FET) or a mechanical switch. The interruption unit 14 switches to the permission state in response to the switch 14 A switching to an ON state, and switches to the interruption state in response to the switch 14A switching to an OFF state. In the present embodiment, the interruption unit 14 is provided in the target side conductive path 8, but the interruption unit 14 may be provided in the power supply unit side conductive path 7 or the positive electrode side conductive path 5.

The control unit 15 includes an information processing device such as a Micro Controller Unit (MCU). The detection value of each of the current sensors 12 is input to the control unit 15. The control unit 15 determines whether or not each of the conductive paths 20 is in an overcurrent state, based on the detection value of each of the current sensors 12. When the detection value of the current sensor 12 exceeds the threshold value, for example, the control unit 15 determines that the conductive path 20 that is the detection target of that current sensor 12 is in the overcurrent state. When it is determined that at least one conductive path 20 (in the present embodiment, at least one of the first conductive path 20A and the second conductive path 20B) is in the overcurrent state, the control unit 15 switches the interruption unit 14 from the permission state to the interruption state.

### Example of Operation of Abnormality Detection Device 10

In a normal state, the control unit 15 turns ON the switch 14A to maintain the interruption unit 14 in the permission state. In this state, power generated from the power supply unit 2 can be supplied to the load 3. The abnormality determination unit 13 repeatedly determines whether or not the difference between the detection value of the first current sensor 12A and the detection value of the second current sensor 12B is outside predetermined numerical range. When it is determined that the difference between the detection value of the first current sensor 12A and the detection value of the second current sensor 12B is outside a predetermined numerical range, the abnormality determination unit 13 determines that there is an abnormality.

The control unit 15 repeatedly determines whether or not at least one of the first conductive path 20A and the second conductive path 20B is in the overcurrent state. When it is determined that at least one of the first conductive path 20A and the second conductive path 20B is in the overcurrent state, the control unit 15 switches the interruption unit 14 from the permission state to the interruption state.

### Example of Effects of Abnormality Detection Device 10

In the abnormality detection device 10, currents distributed between the plurality of conductive paths 20 are detected by the respective current sensors 12, and abnormality determination of the current sensors 12 is performed based on the detection values. Accordingly, with this configuration, the current capacity of each current sensor 12 can be reduced. In the present embodiment, each conductive path 20 is provided with the shunt resistor 21 having the same resistance value. For this reason, the current flowing through each conductive path 20 is halved, making it possible to use the current sensors 12 with which the current capacity is half that of a configuration in which the current sensors 12 are provided in the paths (e.g., the power supply unit side conductive path 7 and the target side conductive path 8) other than the parallel circuit unit 11. Accordingly, the current sensors 12 can be easily downsized.

Further, the abnormality determination unit 13 determines that there is an abnormality at least when it is determined that the difference between the detection value of the first current sensor 12A and the detection value of the second current sensor 12B is outside a predetermined numerical range. With this configuration, the configuration for performs abnormality determination of the current sensors 12 can be more easily simplified.

Further, the abnormality detection device 10 includes the interruption unit 14 that switches from the permission state in which power supply from the power supply unit 2 side to the load 3 side via the parallel circuit unit 11 is permitted, to the interruption state in which this power supply is interrupted. With this configuration, by the interruption unit 14 switching from the permission state to the interruption state, it is possible to interrupt the power supply from the power supply unit 2 side to the load 3 side via the parallel circuit unit 11.

Further, the abnormality detection device 10 includes the control unit 15 that switches the interruption unit 14 from the permission state to the interruption state based on the detection value of at least one of the plurality of current sensors 12. With this configuration, based on the detection value of the current sensor 12, it is possible to interrupt the power supply from the power supply unit 2 side to the load 3 side via the parallel circuit unit 11. Further, an abnormality of the current sensors 12 used for determination regarding switching of the interruption unit 14 can be determined by the abnormality determination unit 13.

Further, the control unit 15 determines whether or not each of the conductive paths 20 is in the overcurrent state, based on the detection value of the corresponding current sensor 12, and when it is determined that at least one conductive path 20 is in the overcurrent state, the control unit 15 switches the interruption unit 14 from the permission state to the interruption state. With this configuration, the plurality of current sensors 12 (in the present embodiment, the first current sensor 12A and the second current sensor 12B) that are used to determine the abnormality can be effectively used for quick switching of the interruption unit 14.

Further, each of the current sensors 12 has the shunt resistor 21 provided in the corresponding conductive path 20. With this configuration, the configuration of the current sensors 12 can be easily simplified.

### Second Embodiment

A power supply system 201 of a second embodiment is different from the power supply system 1 of the first embodiment in the configuration of the current sensors, and similar to the power supply system 1 in other aspects. In the following description, configurations that are the same as the first embodiment are denoted by the same reference signs, and redundant description is omitted.

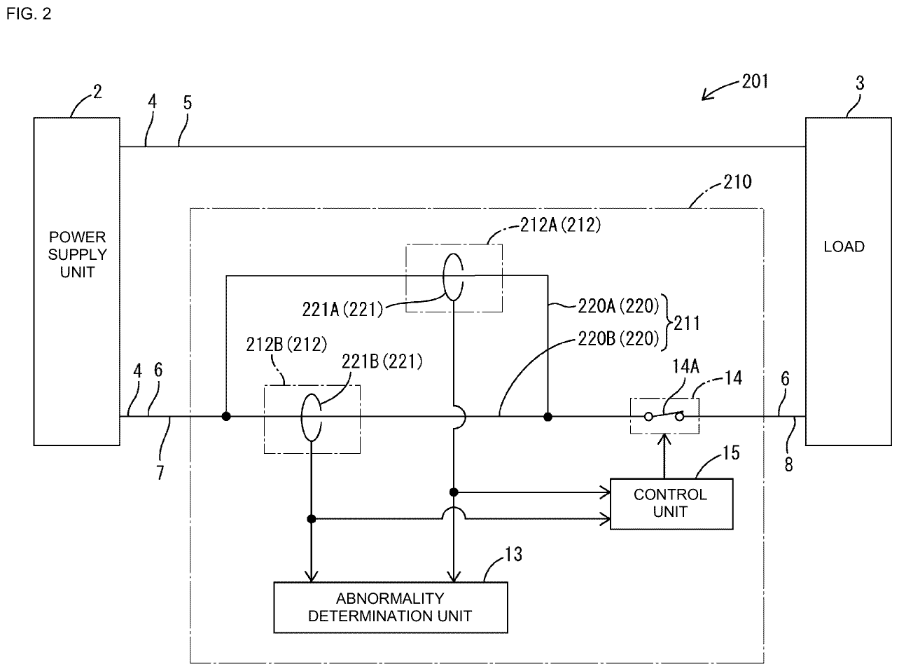

FIG. 2 shows the power supply system 201 of the second embodiment. The power supply system 201 includes the power supply unit 2, the load 3, the power path 4, and an abnormality detection device 210. The abnormality detection device 210 is mounted in a vehicle and used in the power supply system 201. The abnormality detection device 210 includes a parallel circuit unit 211, a plurality of current sensors 212, the abnormality determination unit 13, the interruption unit 14, and the control unit 15.

The parallel circuit unit 211 has a configuration in which a plurality of conductive paths 220 are connected in parallel. The parallel circuit unit 211 is provided between the power supply unit 2 and the load 3. The parallel circuit unit 211 is provided in the power path 4 (more specifically, the negative electrode side conductive path 6) and forms part of the power path 4 (more specifically, the negative electrode side conductive path 6). That is, the parallel circuit unit 211 forms part of the path for supplying power from the power supply unit 2 to the load 3. One end of the parallel circuit unit 211 is short-circuited to the power supply unit side conductive path 7 provided on the power supply unit 2 side with respect to the parallel circuit unit 211, and electrically connected to the power supply unit side conductive path 7. The other end of the parallel circuit unit 211 is electrically connected to the target side conductive path 8 provided on the load 3 side with respect to the parallel circuit unit 211. The plurality of conductive paths 220 are connected in parallel between the power supply unit side conductive path 7 and the target side conductive path 8.

The plurality of conductive paths 220 include a first conductive path 220A and a second conductive path 220B. The first conductive path 220A and the second conductive path 220B are connected in parallel between the power supply unit side conductive path 7 and the target side conductive path 8. One end of each of the conductive paths 220 is short-circuited to the power supply unit side conductive path 7 (more specifically, the other end of the power supply unit side conductive path 7) and electrically connected to the power supply unit side conductive path 7 (more specifically, the other end of the power supply unit side conductive path 7). The other end of each of the conductive paths 220 is short-circuited to the target side conductive path 8 (more specifically, the other end of the target side conductive path 8) and electrically connected to the target side conductive path 8 (more specifically, the other end of the target side conductive path 8).

Each of the current sensors 212 detects a current flowing through the corresponding conductive path 220. The plurality of current sensors 212 include a first current sensor 212A and a second current sensor 212B. The first current sensor 212A detects a current flowing through the first conductive path 220A. The second current sensor 212B detects a current flowing through the second conductive path 220B. Information with which the detection value of each current sensor 212 can be specified is input to the abnormality determination unit 13 and the control unit 15.

Each current sensor 212 is a non-contact sensor disposed, in a non-contact manner, in the conductive path 220 whose current is to be detected. Each current sensor 212 includes a magnetism detection unit 221 that detects magnetism generated by a current flowing through the corresponding conductive path 220 and converts the magnetism into an electric signal. The magnetism detection unit 221 may include a Hall element or a magnetoresistive effect element. The current sensors 212 are not in contact with the conductive paths 220. That is, the other end of the power supply unit side conductive path 7 is short-circuited to the other end of the target side conductive path 8 via the parallel circuit unit 211, and electrically connected to the other end of the target side conductive path 8.

The first current sensor 212A includes a first magnetism detection unit 221A provided in the first conductive path 220A. The first magnetism detection unit 221A detects magnetism generated by a current flowing through the first conductive path 220A and converts the magnetism into an electric signal. The second current sensor 212B includes a second magnetism detection unit 221B provided in the second conductive path 220B. The second magnetism detection unit 221B detects magnetism generated by a current flowing through the second conductive path 220B and converts the magnetism into an electric signal.

The abnormality determination unit 13 performs abnormality determination of the current sensors 212 based on the detection values of the current sensors 212. When the difference between the detection value of the first current sensor 212A and the detection value of the second current sensor 212B is outside a predetermined numerical range, the abnormality determination unit 13 determines that there is an abnormality.

The interruption unit 14 has a function of switching from the permission state in which power supply from the power supply unit 2 side to the load 3 side via the parallel circuit unit 211 is permitted to the interruption state in which the power supply is interrupted.

The control unit 15 determines whether or not each of the conductive paths 220 is in the overcurrent state, based on the detection value of the corresponding current sensor 212. When the detection value of the current sensor 212 exceeds the threshold value, for example, the control unit 15 determines that the conductive path 220 that is the detection target of that current sensor 212 is in the overcurrent state. When it is determined that at least one of the first conductive path 220A and the second conductive path 220B is in the overcurrent state, for example, the control unit 15 switches the interruption unit 14 from the permission state to the interruption state.

With this configuration, a current flowing through the conductive path 220 can be detected without providing a resistor in the conductive path 220.

### Other Embodiments

The present disclosure is not limited to the embodiments described by way of the above descriptions and figures. For example, features of the embodiments described above and below can be combined in any way as long as no contradiction arises. Also, any feature of the embodiments described above and below can also be omitted unless explicitly stated as essential. Note that changes such as the following may be made to the above embodiments.

The number of conductive paths that are connected in parallel to each other may be three or more. The number of current sensors may be three or more.

The method for performing abnormality determination by the abnormality determination unit is not limited to the method in which, when it is determined that the difference between the detection value of the first current sensor and the detection value of the second current sensor is outside a predetermined numerical range, the abnormality determination unit determines that there is an abnormality. For example, a configuration is also possible in which, when it is determined that the difference between the integration value or average value of the plurality of detection values of the first current sensor in a predetermined period and the integration value or average value of the plurality of detection values of the second current sensor in a predetermined period is outside a predetermined numerical range, the abnormality determination unit determines that there is an abnormality. With this configuration, for example, when performing an AD conversion on the detection value of the current sensor, an error caused by the AD conversion can be reduced. Alternatively, a configuration is also possible in which the abnormality determination unit performs determination as to whether or not the value is outside the numerical range a predetermined number of times, and if the percentage of determinations that the value is outside the range exceeds the reference value, it is determined that there is an abnormality.

Also, the method for determining the over current state by the control unit is not limited to the method in which, when the detection value of the current sensor exceeds the threshold value, it is determined that the conductive path that is the detection target of that current sensor is in the overcurrent state. For example, when the integrated value or average value of a plurality of detection values of the current sensor in a predetermined period exceeds the threshold value, the control unit may determine that the conductive path that is the detection target of the current sensor is in the overcurrent state. In another example, when a state in which the detection value of the current sensor exceeds the threshold value continues for a determination period, the control unit may determine that the conductive path that is the detection target of the current sensor is in the overcurrent state. A plurality of patterns of combinations of a threshold value and a determination period may be prepared.

The condition on which the control unit switches the interruption unit to the interruption state is not limited to that at least one of the first conductive path and the second conductive path is determined to be in the overcurrent state. For example, the control unit may also be configured to switch the interruption unit to the interruption state when both the first conductive path and the second conductive path are determined to be in the overcurrent state. With this configuration, the plurality of current sensors used in determination of the abnormality can be effectively used for prevention of erroneous determination of the overcurrent state. In another example, a configuration is also possible in which the control unit monitors only one of the first conductive path and the second conductive path and switches the interruption unit to the interruption state when it is determined that the monitored conductive path is in the overcurrent state. Further, when there are three or more conductive paths, a configuration is also possible in which the control unit switches the interruption unit to the interruption state when all the conductive paths are determined to be in the overcurrent state, or when a predetermined number of the conductive paths are determined to be in the overcurrent state.

A configuration is also possible in which the interruption unit cannot return to the permission state after having switched to the interruption state. For example, the interruption unit may also be a pyrotechnic circuit breaker that disconnects the power path when the driving current is supplied.

The resistance value of the shunt resistor provided in each of the conductive paths need not be the same. This configuration also makes it possible to use a current sensor with a smaller short-circuit tolerance.

The parallel circuit unit may be provided in the positive electrode side conductive path instead of the negative electrode side conductive path.

The abnormality detection device need not necessarily include the interruption unit. The abnormality detection device need not necessarily include the control unit.

The embodiments disclosed here are to be considered in all respects as illustrative and not limiting. The present disclosure is not intended to be limited to these embodiments, but rather is indicated by the scope of the claims, and is intended to include all modifications within the meaning and scope of equivalents of the scope of the claims.

1. An abnormality detection device comprising:
a parallel circuit unit in which a plurality of conductive paths are connected in parallel;
a plurality of current sensors; and
an abnormality determination unit,
wherein the current sensors detect currents respectively flowing through the plurality of conductive paths, and
the abnormality determination unit performs abnormality determination of the current sensors based on the detection values of the plurality of current sensors,
the parallel circuit unit is provided between a power supply unit and a power supply target to which power based on the power supply unit is to be supplied, and
one end of the parallel circuit unit is short-circuited to one power supply side conductive path provided on the power supply unit side with respect to the parallel circuit unit, and another end of the parallel circuit unit is short-circuited to one target side conductive path provided on the power supply target side with respect to the parallel circuit unit.

2. The abnormality detection device according to claim 1,
wherein the plurality of conductive paths include a first conductive path and a second conductive path connected in parallel to each other,
the plurality of current sensors include a first current sensor that detects a current flowing through the first conductive path, and a second current sensor that detects a current flowing through the second conductive path, and
the abnormality determination unit determines that there is an abnormality at least when a difference between a detection value of the first current sensor and a detection value of the second current sensor is outside a predetermined numerical range.

3. The abnormality detection device according to claim 1,
further including an interruption unit configured to switch from a permission state in which power supply from the power supply unit side to the power supply target side via the parallel circuit unit is permitted to an interruption state in which the power supply is interrupted.

4. The abnormality detection device according to claim 3, further comprising a control unit configured to switch the interruption unit from the permission state to the interruption state based on a detection value of at least one of the plurality of current sensors.

5. The abnormality detection device according to claim 4, wherein the control unit determines whether or not each of the conductive paths is in an overcurrent state, based on a detection value of the corresponding current sensor, and, when it is determined that at least one of the conductive paths is in the overcurrent state, switches the interruption unit from the permission state to the interruption state.

6. The abnormality detection device according to claim 4, wherein the control unit determines whether or not each of the conductive paths is in an overcurrent state based on a detection value of the corresponding current sensor, and, when it is determined that two or more of the conductive paths are in the overcurrent state, switches the interruption unit from the permission state to the interruption state.

7. (canceled)

8. The abnormality detection device according to claim 1, wherein each of the current sensors has a shunt resistor provided in the corresponding conductive path.

9. The abnormality detection device according to claim 1, wherein each of the current sensors includes a magnetism detection unit configured to detect magnetism generated by a current flowing through each of the conductive paths and convert the magnetism into an electric signal.

10. The abnormality detection device according to claim 2,
further including an interruption unit configured to switch from a permission state in which power supply from the power supply unit side to the power supply target side via the parallel circuit unit is permitted to an interruption state in which the power supply is interrupted.
